(19) United States
(12) Patent Application Publication
(10) Pub. No.: US 2025/0143114 A1
(43) Pub. Date: May 1, 2025

(54) DISPLAY APPARATUS

(71) Applicant: Samsung Display Co., Ltd., Yongin-si (KR)

(72) Inventors: Sunghwan Kim, Yongin-si (KR); Heyjin Shin, Yongin-si (KR); Daehyun Kim, Yongin-si (KR); Changkyu Jin, Yongin-si (KR)

(21) Appl. No.: 18/740,331

(22) Filed: Jun. 11, 2024

(30) Foreign Application Priority Data
Oct. 27, 2023 (KR) 10-2023-0145930

(51) Int. Cl. H10K 59/131

(52) U.S. Cl. CPC H10K 59/131

(57) ABSTRACT

A display apparatus includes: a substrate; a pixel circuit layer on the substrate; a first conductive layer on the pixel circuit layer, and including a plurality of data lines; a first-1 pixel electrode on the first conductive layer; a second conductive layer between the first conductive layer and the first-1 pixel electrode, and including: a plurality of power lines; and a first-1 shielding portion overlapping with the first-1 pixel electrode in a plan view; and a first-1 light-emitting element on the first-1 pixel electrode. The plurality of power lines and the first-1 shielding portion are integrated with each other.

### CROSS-REFERENCE TO RELATED APPLICATION

The present application claims priority to and the benefit of Korean Patent Application No. 10-2023-0145930, filed on Oct. 27, 2023, in the Korean Intellectual Property Office, the entire disclosure of which is incorporated herein by reference.

### BACKGROUND

### 1. Field

One or more embodiments of the present disclosure relate to a display apparatus.

### 2. Description of the Related Art

A display apparatus is an apparatus that receives information about an image and displays the image. The display apparatus may be used as a display unit of a small-sized product such as a mobile phone, or may be used as a display unit of a large-sized product such as a television.

A display apparatus includes a plurality of pixels that receives electrical signals to emit light to display an image to the outside. Each pixel includes a light-emitting element, for example, such as an organic light-emitting diode (OLED) as the light-emitting element for an organic light-emitting display apparatus. Generally, the organic light-emitting display apparatus includes a thin-film transistor and an OLED on a substrate, and the OLED operates by emitting light by itself.

The above information disclosed in this Background section is for enhancement of understanding of the background of the present disclosure, and therefore, it may contain information that does not constitute prior art.

### SUMMARY

A display apparatus may have image quality deterioration due to parasitic capacitors, for example, such as a mura phenomenon that may occur due to the parasitic capacitors.

One or more embodiments of the present disclosure may be directed to a display apparatus capable of reducing image quality deterioration due to a parasitic capacitor. However, the aspects and features of the present disclosure are not limited thereto.

Additional aspects and features will be set forth, in part, in the description that follows, and in part, will be apparent from the description, or may be learned by practicing one or more of the presented embodiments of the present disclosure.

According to one or more embodiments of the present disclosure, a display apparatus includes: a substrate; a pixel circuit layer on the substrate; a first conductive layer on the pixel circuit layer, and including a plurality of data lines; a first-1 pixel electrode on the first conductive layer; a second conductive layer between the first conductive layer and the first-1 pixel electrode, and including: a plurality of power lines; and a first-1 shielding portion overlapping with the first-1 pixel electrode in a plan view; and a first-1 light-emitting element on the first-1 pixel electrode. The plurality of power lines and the first-1 shielding portion are integrated with each other.

In an embodiment, the display apparatus may further include: a second-1 pixel electrode on the first conductive layer and at a same layer as that of the first-1 pixel electrode; a second-1 light-emitting element on the second-1 pixel electrode; a third-1 pixel electrode on the first conductive layer and at a same layer as that of the second-1 pixel electrode; and a third-1 light-emitting element on the third-1 pixel electrode.

In an embodiment, the second conductive layer may further include a second-1 shielding portion at a same layer as that of the first-1 shielding portion, and located between the first conductive layer and the second-1 pixel electrode.

In an embodiment, the plurality of power lines, the first-1 shielding portion, and the second-1 shielding portion may be integrated with each other.

In an embodiment, the plurality of power lines may include: a first vertical power line extending in a first direction; and a first horizontal power line extending in a second direction crossing the first direction, and integrated with the first vertical power line.

In an embodiment, the second conductive layer may further include a third-1 shielding portion at a same layer as that of the first-1 shielding portion, and located between the first conductive layer and the second-1 pixel electrode.

In an embodiment, in a plan view, a shape of the first-1 shielding portion may correspond to a shape of the first-1 light-emitting element.

In an embodiment, in a plan view, an area of the first-1 light-emitting element may be less than an area of the first-1 shielding portion.

In an embodiment, the first-1 shielding portion may be located between at least one of the plurality of data lines and the first-1 pixel electrode, the at least one of the plurality of data lines overlapping with the first-1 pixel electrode in a plan view.

In an embodiment, in a plan view, a shape of the second-1 shielding portion may correspond to a shape of the second-1 light-emitting element.

In an embodiment, in a plan view, an area of the second-1 light-emitting element may be less than an area of the second-1 shielding portion.

In an embodiment, the second-1 shielding portion may be located between at least one of the plurality of data lines and the second-1 pixel electrode, the at least one of the plurality of data lines overlapping with the second-1 pixel electrode in a plan view.

In an embodiment, in a plan view, a shape of the third-1 shielding portion may correspond to a shape of the third-1 light-emitting element.

In an embodiment, in a plan view, an area of the third-1 light-emitting element may be less than an area of the third-1 shielding portion.

In an embodiment, the third-1 shielding portion may be located between at least one of the plurality of data lines and the third-1 pixel electrode, the at least one of the plurality of data lines overlapping with the third-1 pixel electrode in a plan view.

In an embodiment, the first conductive layer may further include: a first vertical data line around the plurality of data lines, and extending in a first direction; and a first horizontal data line extending in a second direction crossing the first direction, and electrically connected to the first vertical data line.

In an embodiment, the first horizontal data line may include a first-1 horizontal data line, and a first-2 horizontal data line spaced from the first-1 horizontal data line. The first-1 horizontal data line and the first-2 horizontal data line may be electrically connected to each other by a first-1 bridge line at a same layer as that of the second conductive layer.

In an embodiment, the first-1 bridge line may include a same material as that of the second conductive layer.

In an embodiment, in a plan view, the first-1 bridge line may be spaced from the plurality of power lines and the first-1 shielding portion.

In an embodiment, in a plan view, an area of the first-1 pixel electrode may be greater than an area of the first-1 shielding portion.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a plan view schematically illustrating a display panel of a display apparatus according to an embodiment;

FIG. 2 is an equivalent circuit diagram showing an example of a pixel of the display panel of FIG. 1;

FIG. 3 is an equivalent circuit diagram showing an example of a pixel of the display panel of FIG. 1;

FIG. 4 is a cross-sectional view schematically illustrating an example of a cross section of a pixel of the display panel of FIG. 1;

FIG. 5 is a cross-sectional view schematically illustrating another example of a cross section of a pixel of the display panel of FIG. 1;

FIG. 6 is a schematic plan view illustrating an enlarged example of the area A of FIG. 1;

FIG. 7 is a schematic plan view of a second conductive layer of FIG. 6;

FIG. 8 is a schematic plan view mainly illustrating another enlarged example of the area A of FIG. 1;

FIGS. 9-16 are example layout diagrams schematically illustrating various layers of components of a partial area of the area A of FIG. 1;

FIG. 17 is a layout diagram schematically illustrating an example of an overlap of the layout diagrams of FIGS. 9 through 16; and

FIG. 18 is an example enlarged diagram schematically illustrating a stacked layout of a second conductive layer, a light-emitting element, and a pixel electrode according to an embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

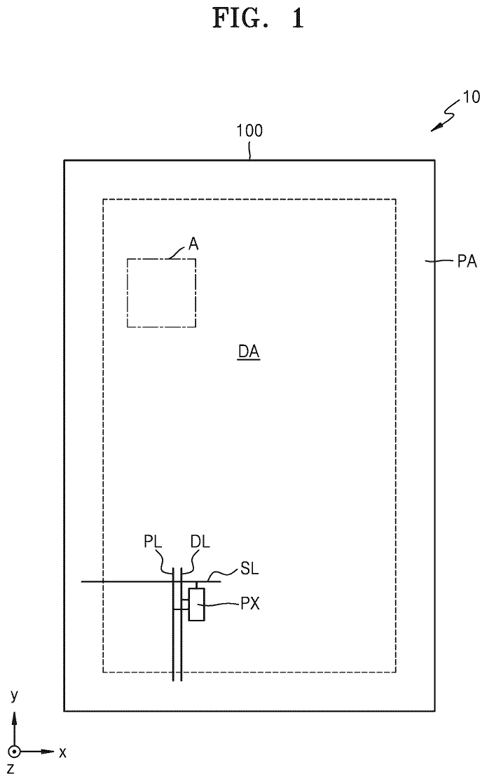

FIG. 1 is a plan view schematically illustrating a display panel of a display apparatus according to an embodiment.

As shown in FIG. 1, the display apparatus according to an embodiment may include a display panel 10. Any suitable display apparatus may be implemented, as long as it includes the display panel 10. For example, the display apparatus may be various suitable apparatuses, such as a smart phone, a tablet, a laptop, a television, a billboard, or the like. The display apparatus according to an embodiment includes thin-film transistors, a capacitor, or the like, and the thin-film transistors, the capacitor, or the like may be implemented by conductive layers and insulating layers.

The display panel 10 includes a display area DA, and a peripheral area PA positioned outside the display area DA. In FIG. 1, the display area DA is shown to have a rectangular shape. However, the present disclosure is not limited thereto. The display area DA may have various suitable shapes, for example, such as a circular shape, an oval shape, a polygonal shape, a shape of a particular figure, or the like.

The display area DA is a portion that displays an image, and a plurality of pixels PX may be arranged in the display area DA. Each of the plurality of pixels PX may include a display element, such as an organic light-emitting diode. Each pixel PX may emit, for example, red, green, or blue light. The pixel PX may be connected to a pixel circuit including a thin-film transistor (TFT), a storage capacitor, or the like. The pixel circuit may be connected to a scan line SL that transmits a scan signal, a data line DL that crosses the scan line SL and transmits a data signal, and a driving voltage line PL that supplies a driving voltage. The scan line SL may extend in the x direction (hereinafter referred to as a second direction), and the data line DL and the driving voltage line PL may extend in the y direction (hereinafter referred to as a first direction).

The pixel PX may emit light having a brightness corresponding to an electrical signal from the pixel circuit that is electrically connected to the pixel PX. The display area DA may display an image (e.g., a certain or predetermined image) through light emitted from the pixel PX. The pixel PX may be defined as an emission area for emitting light of any one color of red, green, and/or blue, as described above.

The peripheral area PA is an area in which the pixel PX is not arranged, and may be an area that does not display an image. A power supply line for driving the pixel PX or the like may be positioned in the peripheral area PA. Also, a plurality of pads may be arranged in the peripheral area PA. A printed circuit board including a driving circuit unit (e.g., a driving circuit) or an integrated circuit device, such as a driver integrated circuit (IC), may be arranged in the peripheral area PA to be electrically connected to the plurality of pads.

Because the display panel 10 includes a substrate 100, the substrate 100 may be understood as having the display area DA and the peripheral area PA. The substrate 100 is described in more detail below.

In FIG. 1, the area A may refer to a partial area of the display area DA. For convenience, the area A may be mainly described in more detail hereinafter, and the structure of the display area DA may be understood as having a repeated structure of the area A or similar to the structure of the area A.

A plurality of transistors may be arranged in the display area DA. According to the kind of the transistors (e.g., N-type or P-type) and/or an operating condition, a first terminal of each of the plurality of transistors may be a source electrode or a drain electrode, and a second terminal thereof may be an electrode different from the first terminal. For example, when the first terminal is the source electrode, the second terminal may be the drain electrode.

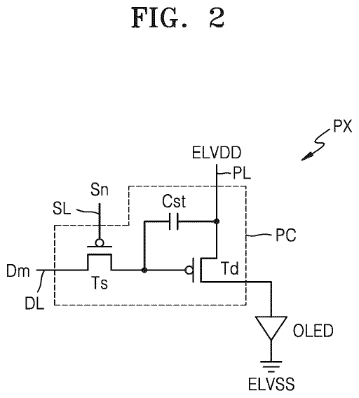

The plurality of transistors may include a driving transistor, a data write transistor, a compensation transistor, an initialization transistor, an emission control transistor, or the like. The driving transistor may be connected between the driving voltage line PL and an organic light-emitting diode OLED (e.g., refer to FIG. 2). The data write transistor may be connected to the data line DL and the driving transistor, and may perform a switching operation for transmitting a data signal that is transmitted through the data line DL.

The compensation transistor may be turned on in response to a scan signal received through the scan line SL, and may connect the driving transistor to the organic light-emitting diode OLED to compensate for a threshold voltage of the driving transistor.

The initialization transistor may be turned on in response to a scan signal received through the scan line SL, and transmit an initialization voltage to a gate electrode of the driving transistor to initialize the gate electrode of the driving transistor. A scan line connected to the compensation transistor may be a separate scan line from the scan line SL connected to the initialization transistor.

The emission control transistor may be turned on in response to an emission control signal received through an emission control line, and accordingly, a driving current may flow to the organic light-emitting diode OLED.

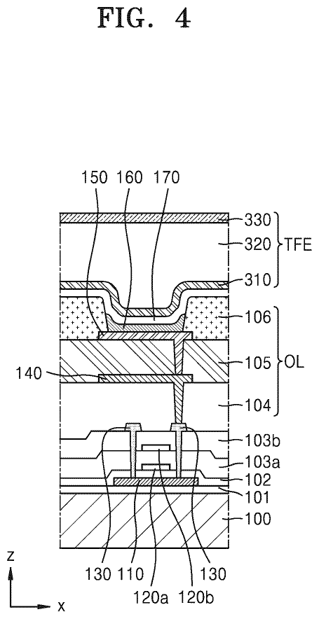

The organic light-emitting diode OLED may include a pixel electrode (e.g., an anode) and an opposite electrode (e.g., a cathode). The opposite electrode 170 (e.g., refer to FIG. 4) may receive a second power supply voltage ELVSS (e.g., refer to FIG. 2). The organic light-emitting diode OLED may display an image by receiving the driving current from the driving transistor to emit light.

Hereinafter, an organic light-emitting display apparatus is described in more detail as a representative example of the display apparatus according to an embodiment, but the present disclosure is not limited thereto. In another embodiment, the display apparatus may be an inorganic light-emitting display apparatus (e.g., inorganic light-emitting display or inorganic EL display apparatus) or a quantum dot light-emitting display apparatus. For example, an emission layer of a display element included in the display apparatus may include an organic material or an inorganic material. Also, the display apparatus may include an emission layer, and a quantum dot positioned on a path of light emitted by the emission layer.

FIG. 2 is an equivalent circuit diagram showing an example of a pixel of the display panel of FIG. 1.

As shown in FIG. 2, each pixel PX includes a pixel circuit PC connected to a corresponding scan line SL and a corresponding data line DL, and an organic light-emitting diode OLED connected to the pixel circuit PC.

The pixel circuit PC includes a driving thin-film transistor Td, a switching thin-film transistor Ts, and a storage capacitor Cst. The switching thin-film transistor Ts is connected to the scan line SL and the data line DL, and transmits, to the driving thin-film transistor Td, a data signal Dm input through the data line DL in response to a scan signal Sn input through the scan line SL.

The storage capacitor Cst is connected to the switching thin-film transistor Ts and the driving voltage line PL, and stores a voltage corresponding to a difference between a voltage received from the switching thin-film transistor Ts and a first power supply voltage ELVDD supplied to the driving voltage line PL.

The second power supply voltage ELVSS may be a driving voltage having a relatively lower level compared to that of the first power supply voltage ELVDD. A level of a driving voltage supplied to each pixel PX may be a difference between the levels of the first power supply voltage ELVDD and the second power supply voltage ELVSS.

The driving thin-film transistor Td may be connected to the driving voltage line PL and the storage capacitor Cst, and may control a driving current to flow from the driving voltage line PL to the organic light-emitting diode OLED, in accordance to a voltage value stored in the storage capacitor Cst. The organic light-emitting diode OLED may emit light having a desired brightness (e.g., a certain or predetermined brightness) according to the driving current.

Although FIG. 2 illustrates that the pixel circuit PC includes two thin-film transistors and one storage capacitor, the present disclosure is not limited thereto. The pixel circuit PC may also include two or more storage capacitors.

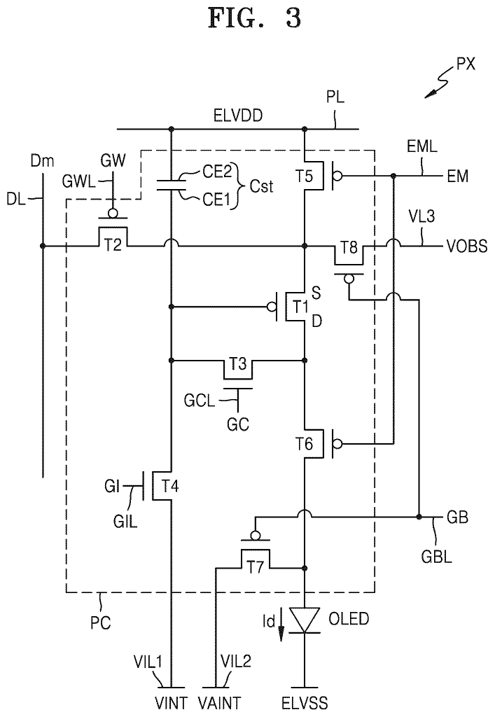

FIG. 3 is an equivalent circuit diagram showing an example of a pixel of the display panel of FIG. 1.

Hereinafter, redundant description as those above with reference to FIG. 2 may not be repeated with reference to FIG. 3. In addition, FIG. 3 illustrates that the pixel circuit PC includes eight thin-film transistors and one storage capacitor, but the present disclosure is not limited thereto. The pixel circuit PC may also include two or more storage capacitors.

Referring to FIG. 3, the pixel circuit PC may include first to eighth transistors T1 to T8. According to a transistor type (e.g., P-type or N-type) and/or an operating condition, a first terminal of each of the first to eighth transistors T1 to T8 may be a source terminal or a drain terminal, and a second terminal thereof may be a terminal different from the first terminal.

For example, when the first terminal is the source terminal, the second terminal may be the drain terminal. The first transistor T1 may be a driving transistor having a magnitude of a source-drain current thereof that is determined according to a gate-source voltage thereof. The second to eighth transistors T2 to T8 may each serve as a switching transistor or the like, which is turned on/off in response to a gate-source voltage thereof, or a gate voltage or substantially the gate voltage thereof.

The pixel circuit PC may be connected to a first gate line GWL that transmits a first gate signal GW, a second gate line GIL that transmits a second gate signal GI, a third gate line GCL that transmits a third gate signal GC, a fourth gate line GBL that transmits a fourth gate signal GB, an emission control line EML that transmits an emission control signal EM, the data line DL that transmits the data signal Dm, the driving voltage line PL that transmits the first power supply voltage ELVDD, a first initialization voltage line VIL1 that transmits a first initialization voltage VINT, and a second initialization voltage line VIL2 that transmits a second initialization voltage VAINT.

The first transistor T1 may include a gate and source/drain terminals. The first transistor T1 receives the data signal Dm according to a switching operation of the second transistor T2, and supplies the driving current to a light-emitting element. The light-emitting element may be an organic light-emitting diode OLED. The gate of the first transistor T1 may be a first electrode CE1 of the storage capacitor Cst.

The second transistor T2 may include a gate connected to the first gate line GWL, a first terminal connected to the data line DL, and a second terminal connected to the first transistor T1 and the eighth transistor T8. The second transistor T2 may be turned on in response to the first gate signal GW received through the first gate line GWL, and may perform a switching operation for providing the data signal Dm provided to the data line DL to the first transistor T1. For example, the second transistor T2 may be a data write transistor.

The third transistor T3 may include a gate connected to the third gate line GCL. The third transistor T3 may be turned on in response to the third gate signal GC received through the third gate line GCL to diode-connect the first transistor T1. For example, the third transistor T3 may be a compensation transistor.

The fourth transistor T4 may include a gate connected to the second gate line GIL, a first terminal connected to the first initialization voltage line VIL1, and a second terminal connected to the first electrode CE1 of the storage capacitor Cst. The fourth transistor T4 may be turned on in response to the second gate signal GI received through the second gate line GIL, and transmits the first initialization voltage VINT to the gate of the first transistor T1 to initialize a gate voltage of the first transistor T1. For example, the fourth transistor T4 may be a first initialization transistor.

The fifth transistor T5 may include a gate connected to the emission control line EML, a first terminal connected to the driving voltage line PL, and a second terminal connected to the first transistor T1. For example, the fifth transistor T5 may be a first emission control transistor.

The sixth transistor T6 may include a gate connected to the emission control line EML, a first terminal connected to the first transistor T1 and the third transistor T3, and a second terminal connected to a pixel electrode of the organic light-emitting diode OLED. The sixth transistor T6 may be a second emission control transistor.

The fifth transistor T5 and the sixth transistor T6 may be concurrently or substantially simultaneously turned on in response to the emission control signal EM received through the emission control line EML, and thus, the driving current may flow to the organic light-emitting diode OLED.

The seventh transistor T7 may include a gate included to the fourth gate line GBL, a first terminal connected to the sixth transistor T6 and the pixel electrode of the organic light-emitting diode OLED, and a second terminal connected to the second initialization voltage line VIL2. The seventh transistor T7 may be turned on in response to the fourth gate signal GB received through the fourth gate line GBL, and transmits the second initialization voltage VAINT to the pixel electrode of the organic light-emitting diode OLED to initialize the pixel electrode of the organic light-emitting diode OLED. For example, the seventh transistor T7 may be a second initialization transistor. However, the seventh transistor T7 may be omitted as needed or desired.

The eighth transistor T8 may include a gate connected to the fourth gate line GBL, a first terminal connected to the first transistor T1, and a second terminal connected to a bias voltage line VL3 that transmits an on-bias voltage VOBS. The eighth transistor T8 may be turned on in response to the fourth gate signal GB received through the fourth gate line GBL, and transmits the on-bias voltage VOBS to the first transistor T1. In this case, the first transistor T1 may be in an on-bias state, and threshold voltage characteristics of the first transistor T1 may be changed. Accordingly, in low-frequency driving, characteristics of the first transistor T1 may be fixed (e.g., changed) to a particular state to prevent or substantially prevent deterioration.

The storage capacitor Cst may include the first electrode CE1 connected to the gate of the first transistor T1, and a second electrode CE2 connected to the driving voltage line PL.

The organic light-emitting diode OLED may include the pixel electrode and a common electrode facing the pixel electrode, and the common electrode may receive the second power supply voltage ELVSS. The organic light-emitting diode OLED may receive a driving current from the first transistor T1, and may emit light having a certain color to display an image.

In FIGS. 2 and 3, the driving thin-film transistor Td, the switching thin-film transistor Ts, the first transistor T1, the second transistor T2, and the fifth to eighth transistors T5 to T8 of the pixel circuits PC are shown as P-type transistors, but the present disclosure is not limited thereto. For example, the first to eighth transistors T1 to T8 of the pixel circuit PC may be N-type transistors, or some of the first to eighth transistors T1 to T8 may be P-type transistors and others thereof may be N-type transistors.

FIG. 4 is a cross-sectional view schematically illustrating an example of a cross section of a pixel of the display panel of FIG. 1.

Hereinafter, with reference to FIG. 4, redundant description of the same or substantially the same components as those described above with reference to FIGS. 1 to 3 may not be repeated.

The substrate 100 may include areas corresponding to the display area DA, and the peripheral area PA outside the display area DA. The substrate 100 may include various suitable materials that are flexible or bendable. For example, the substrate 100 may include glass, a metal, or a polymer resin. The substrate 100 may include the polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers, each including the polymer resin, and a barrier layer including an inorganic material (e.g., silicon oxide, silicon nitride, silicon oxynitride, or the like) arranged between the two layers. However, the present disclosure is not limited thereto, and various modifications may be made.

In some embodiments, to implement an ultra-high resolution, the substrate 100 may include a semiconductor material, for example, such as a group IV semiconductor, a group III-V compound semiconductor, or a group II-VI compound semiconductor. The substrate 100 may include a silicon layer. In other words, the substrate 100 may be a semiconductor substrate including a semiconductor material. The substrate 100 may include a silicon wafer formed by using a semiconductor process. In this case, an active layer may be formed inside the substrate 100 including the silicon wafer, and a gate line, a data line, and a transistor may be disposed on an upper surface of the substrate 100. As such, an organic light-emitting diode OLED using the substrate including the silicon wafer may be referred to as OLED-on-silicon (OLEDoS). For example, in the case of OLEDoS, a complementary metal-oxide semiconductor (CMOS) process may be used to form finer pixels, and an OLED device may be formed on an electrode formed through the CMOS process. To implement colors of red (R), green (G), and blue (B), respectively, in the OLEDOS, a white OLED may be generally made, and color filters may be disposed on the white OLED to implement the colors of red (R), green (G), and blue (B). OLEDOS may be mainly used for extended reality (XR), and ultra-high image quality of 8K or more may be implemented in a smaller area of about 1 to 2 inches. When a semiconductor substrate is used, precise control of the pixels arranged at an ultra-high resolution may be possible. However, the present disclosure is not limited thereto.

A buffer layer 101 may be positioned on the substrate 100. The buffer layer 101 may function as a barrier layer and/or a blocking layer to prevent or substantially prevent impurity ions from diffusing, prevent or substantially prevent moisture and/or external air from penetrating, and planarize or substantially planarize the surface of the substrate 100. The buffer layer 101 may include silicon oxide, silicon nitride, or silicon oxynitride. Also, the buffer layer 101 may adjust a heat supply rate during a crystallization process for forming a semiconductor layer 110, so that the semiconductor layer 110 is uniformly or substantially uniformly crystallized.

The semiconductor layer 110 may be positioned on the buffer layer 101. The semiconductor layer 110 may include polysilicon or an oxide semiconductor. The semiconductor layer 110 may include a channel area that is not doped (or that is more lightly doped) with an impurity, and a source area and a drain area, which are formed by doping impurities on both sides (e.g., opposite sides) of the channel area, respectively. Here, the impurity may vary depending on the kind of thin-film transistor to be implemented, and may be an N-type impurity or a P-type impurity.

For example, a display apparatus according to an embodiment may include a plurality of transistors, and at least one of the plurality of transistors may include an oxide semiconductor.

A gate insulating film 102 may be positioned on the semiconductor layer 110. The gate insulating film 102 may secure an insulation between the semiconductor layer 110 and a first gate layer 120a. The gate insulating film 102 may include an inorganic material, such as silicon oxide, silicon nitride, and/or silicon oxynitride, and may be disposed between the semiconductor layer 110 and the first gate layer 120a. Also, the gate insulating film 102 may have a shape corresponding to the entire or substantially entire surface of the substrate 100, and may have a structure in which contact holes are formed in (e.g., penetrate) a portion (e.g., a predetermined portion) thereof. As such, an insulating film including an inorganic material may be formed through chemical vapor deposition (CVD) or atomic layer deposition (ALD). The above may be similarly applied to the embodiments and modification examples described in more detail below.

The first gate layer 120a may be positioned on the gate insulating film 102. The first gate layer 120a may be arranged at a position vertically overlapping with the semiconductor layer 110, and may include at least one metal from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and/or copper (Cu).

A first interlayer insulating film 103a may be positioned on the first gate layer 120a. The first interlayer insulating film 103a may cover the first gate layer 120a. The first interlayer insulating film 103a may include an inorganic material. For example, the first interlayer insulating film 103a may include a metal oxide or a metal nitride, and the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like. The first interlayer insulating film 103a may include a double structure of SiOₓ/SiN_{y} or SiNₓ/SiO_{y} in some embodiments.

A second gate layer 120b may be positioned on the first interlayer insulating film 103a. The second gate layer 120b may be arranged at a position vertically overlapping with the first gate layer 120a, and may include at least one metal from among Mo, Al, Pt, Pd, Ag, Mg, Au, Ni, Nd, Ir, Cr, Li, Ca, Ti, W, and/or Cu.

In some embodiments, the second gate layer 120b may form the storage capacitor Cst described above with reference to FIG. 3 with the first gate layer 120a. The first gate layer 120a may be one electrode of the storage capacitor Cst, and the second gate layer 120b may be another electrode of the storage capacitor Cst.

A second interlayer insulating film 103b may be positioned on the second gate layer 120b. The second interlayer insulating film 103b may cover the second gate layer 120b. The second interlayer insulating film 103b may include an inorganic material. For example, the second interlayer insulating film 103b may include a metal oxide or a metal nitride, and the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like. The second interlayer insulating film 103b may include a double structure of SiOₓ/SiN_{y} or SiNₓ/SiO_{y} in some embodiments.

A first conductive layer 130 may be positioned on the second interlayer insulating film 103b. The first conductive layer 130 may function as an electrode that is connected to a source/drain area of the semiconductor layer 110 through a through hole included in (e.g., penetrating) the second interlayer insulating film 103b. The first conductive layer 130 may include at least one metal selected from among Al, Pt, Pd, Ag, Mg, Au, Ni, Nd, Ir, Cr, Li, Ca, Mo, Ti, W, and/or Cu. For example, the first conductive layer 130 may include a Ti layer, an Al layer, and/or a Cu layer.

A first organic insulating layer 104 may be positioned on the first conductive layer 130. The first organic insulating layer 104 may be an organic insulating layer covering an upper portion of the first conductive layer 130, and having a flat or substantially flat upper surface to function as a planarization film. The first organic insulating layer 104 may include, for example, an organic material, such as acryl, benzocyclobutene (BCB), hexamethyldisiloxane (HMDSO), or the like. The first organic insulating layer 104 may be variously modified as needed or desired, for example, such as to have a single layer structure or a multi-layered structure.

A second conductive layer 140 may be positioned on the first organic insulating layer 104. The second conductive layer 140 may function as an electrode that is connected to a source/drain area of the semiconductor layer 110 through a through hole included in (e.g., penetrating) the first organic insulating layer 104. The second conductive layer 140 may include at least one metal selected from among Al, Pt, Pd, Ag, Mg, Au, Ni, Nd, Ir, Cr, Li, Ca, Mo, Ti, W, and/or Cu. For example, the second conductive layer 140 may include a Ti layer, an Al layer, and/or a Cu layer.

A second organic insulating layer 105 may be positioned on the second conductive layer 140. The second organic insulating layer 105 may be an organic insulating layer covering an upper portion of the second conductive layer 140, and having a flat or substantially flat upper surface to function as a planarization film. The second organic insulating layer 105 may include, for example, an organic material, such as acryl, BCB, HMDSO, or the like. The second organic insulating layer 105 may be various modified as needed or desired, for example such as to have a single layer structure or a multi-layered structure.

In addition, in some embodiments, an additional conductive layer and an additional insulating layer may be further disposed between a conductive layer and a pixel electrode 150, and this may be applicable to the various embodiments of the present disclosure. In this case, the additional conductive layer may include the same material as that of the above-described conductive layer, and may have the same layered structure. The additional insulating layer may include the same material as that of the above-described organic insulating layer, and may have the same layered structure.

The pixel electrode 150 may be positioned on the second organic insulating layer 105. The pixel electrode 150 may be connected to the second conductive layer 140 through a contact hole formed in (e.g., penetrating) the second organic insulating layer 105. A display element may be positioned on the pixel electrode 150.

An organic light-emitting diode (OLED) may be used as the display element. In other words, the OLED may be disposed, for example, on the pixel electrode 150. The pixel electrode 150 may include a transparent conductive layer including a transparent conductive oxide, such as ITO, In₂O₃, IZO, or the like, and a reflective layer including a metal, such as Al, Ag, or the like. For example, the pixel electrode 150 may have a triple-layered structure of ITO/Ag/ITO.

A pixel defining layer 106 may be positioned on the second organic insulating layer 105, and may be arranged to cover an edge of the pixel electrode 150. In other words, the pixel defining layer 106 may cover the edge of the pixel electrode 150. The pixel defining layer 106 may have an opening portion corresponding to the pixel PX, and the opening portion may be formed to expose at least a central portion of the pixel electrode 150. The pixel defining layer 106 may include, for example, an organic material, such as polyimide or HMDSO, or may include an inorganic material, such as a silicon compound (e.g., SiNₓ, SiOₓ, or the like).

In some embodiments, a spacer may be further disposed on the pixel defining layer 106. The spacer may be positioned in the peripheral area PA, and may also be positioned in the display area DA. The spacer may prevent or substantially prevent the OLED from being damaged by a sagging of a mask during a manufacturing process using the mask. The spacer may include an organic insulating material, and may be formed as a single layer or multi-layers.

Hereinafter, for convenience, the first organic insulating layer 104, the second organic insulating layer 105, and the pixel defining layer 106 may be referred to as a plurality of organic insulating films or layers OL.

An intermediate layer 160 may be disposed on the pixel electrode 150. For example, the intermediate layer 160 may be positioned in the opening portion of the pixel defining layer 106. For example, the intermediate layer 160 and an opposite electrode 170 may be positioned in the opening portion of the pixel defining layer 106.

The intermediate layer 160 may include a low-molecular-weight material or a polymer material. The intermediate layer 160 may include a hole injection layer, a hole transport layer, an emission layer, an electron transport layer, and/or an electron injection layer, or the like.

The opposite electrode 170 may include a transparent conductive layer including a transparent conductive oxide, such as ITO, In₂O₃, IZO, or the like. As another example, the opposite electrode 170 may be a conductive layer including Ag and/or Mg. The pixel electrode 150 is used as an anode, and the opposite electrode 170 is used as a cathode. The polarities of the electrodes may be applied in reverse.

However, a structure of the intermediate layer 160 is not limited thereto, and may have various suitable structures. For example, at least one of the layers configuring the intermediate layer 160 may be integrally formed with the opposite electrode 170. As another example, the intermediate layer 160 may include a layer that is patterned to correspond to each of a plurality of pixel electrodes 150.

The opposite electrode 170 may be arranged in the display area DA, and may cover the entire or substantially entire surface of the display area DA. For example, the opposite electrode 170 may be integrated to cover a plurality of pixels. The opposite electrode 170 may be in electrical contact with a power supply line that is arranged in the peripheral area PA. In an embodiment, the opposite electrode 170 may extend to a blocking wall.

A thin-film encapsulation layer TFE may be disposed on the opposite electrode 170. The thin-film encapsulation layer TFE may be arranged to entirely cover the display area DA, and may extend toward the peripheral area PA to cover at least a portion of the peripheral area PA.

The thin-film encapsulation layer TFE may include a first inorganic encapsulation layer 310, a second inorganic encapsulation layer 330, and an organic encapsulation layer 320 between the first inorganic encapsulation layer 310 and the second inorganic encapsulation layer 330. The first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and/or silicon oxynitride.

The organic encapsulation layer 320 may include a monomer-based material or a polymer-based material. The polymer-based material may include an acrylic resin, an epoxy resin, polyimide, polyethylene, or the like. In an embodiment, the organic encapsulation layer 320 may include acrylate.

A blocking wall may be positioned in the peripheral area PA of the substrate 100. In an embodiment, the blocking wall may include a portion of the first organic insulating layer 104, a portion of the second organic insulating layer 105, a portion of the pixel defining layer 106, and a portion of the spacer, but the present disclosure is not limited thereto.

In some cases, the blocking wall may be arranged to surround (e.g., around a periphery of) the display area DA, and may prevent or substantially prevent the organic encapsulation layer 320 of the thin-film encapsulation layer TFE from overflowing to the outside of the substrate 100.

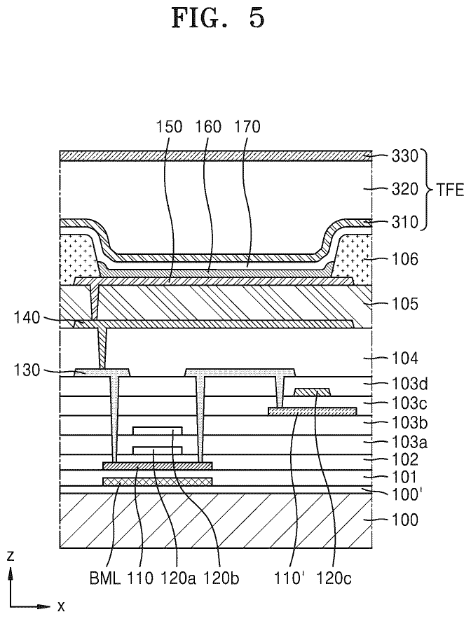

FIG. 5 is a cross-sectional view schematically illustrating another example of a cross section of a pixel of the display panel of FIG. 1.

Hereinafter, with reference to FIG. 5, redundant description of the same or substantially the same components as those described above with reference to FIGS. 1 to 4 may not be repeated.

Referring to FIG. 5, the display apparatus according to an embodiment may further include a bottom metal layer BML between the substrate 100 and the semiconductor layer 110. The display apparatus may include (e.g., may only include) one bottom metal layer BML, or two or more bottom metal layers BML. The bottom metal layer BML may cover at least a portion of the display area DA.

The bottom metal layer BML may be arranged to correspond to lower portions of lines and lower portions of a plurality of transistors of the display apparatus. The bottom metal layer BML may prevent or substantially prevent external light from reaching the lines. Also, the bottom metal layer BML may prevent or substantially prevent external light from reaching the semiconductor layer 110. The bottom metal layer BML may include a metal, such as silver, copper, aluminum, or the like.

As used herein, external light may refer to light entering from the outside of a rear surface of the display apparatus, or light reaching the rear surface through a front surface of the display apparatus that returns to the display apparatus by being reflected by the rear surface of the display apparatus.

As shown in FIG. 5, the buffer layer 101 may be disposed between the bottom metal layer BML and the semiconductor layer 110. The buffer layer 101 may cover an upper surface of the bottom metal layer BML. An additional insulating layer 100′ including an inorganic material may be further included between the bottom metal layer BML and the substrate 100.

As shown in FIG. 5, the display apparatus may further include an additional semiconductor layer 110′. The additional semiconductor layer 110′ may be disposed on the second interlayer insulating film 103b. The additional semiconductor layer 110′ may include polysilicon or an oxide semiconductor, for example, such as the oxide semiconductor. The additional semiconductor layer 110′ may include a channel area that is not doped (or that is more lightly doped) with an impurity, and a source area and a drain area formed by doping impurities on both sides (e.g., opposite sides) of the channel area, respectively. Here, the impurity may be variously modified depending on the kind of thin-film transistor to be implemented, and may be an N-type impurity or a P-type impurity.

For example, the display apparatus according to an embodiment may include a plurality of transistors, and at least one of the plurality of transistors may be configured by the additional semiconductor layer 110′ including an oxide semiconductor.

An additional gate insulating film 103c may be disposed on the additional semiconductor layer 110′. The additional gate insulating film 103c may cover the additional semiconductor layer 110′. The additional gate insulating film 103c may secure an insulation between the additional semiconductor layer 110′ and a third gate layer 120c. The additional gate insulating film 103c may include an inorganic material, such as silicon oxide, silicon nitride, and/or silicon oxynitride, and may be disposed between the additional semiconductor layer 110′ and the third gate layer 120c. Also, like the additional gate insulating film 103c, an insulating film including an inorganic material may be formed through CVD or ALD. The above description is similar to the embodiments and modification examples thereof to be described below.

The third gate layer 120c may be disposed on the additional gate insulating film 103c. The third gate layer 120c may be arranged at a position vertically overlapping with the additional semiconductor layer 110′, and may include at least one metal from among Mo, Al, Pt, Pd, Ag, Mg, Au, Ni, Nd, Ir, Cr, Li, Ca, Ti, W, and/or Cu.

A third interlayer insulating film 103d may be disposed on the third gate layer 120c. The third interlayer insulating film 103d may cover the third gate layer 120c. The third interlayer insulating film 103d may include an inorganic material. For example, the third interlayer insulating film 103d may be a metal oxide or a metal nitride. For example, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like. The third interlayer insulating film 103d may include a double structure of SiOₓ/SiN_{y} or SiNₓ/SiO_{y} in some embodiments.

The first conductive layer 130 may be electrically connected to a portion of the semiconductor layer 110 and a portion of the additional semiconductor layer 110′ through holes. For example, the first conductive layer 130 may be electrically connected to a portion of the semiconductor layer 110 through one through hole. For example, the first conductive layer 130 may be electrically connected to a portion of the additional semiconductor layer 110′ through another through hole.

As described above, the first organic insulating layer 104 or the like may be disposed on the first conductive layer 130. The second conductive layer 140 may be disposed on the first organic insulating layer 104. The second organic insulating layer 105 may be disposed on the second conductive layer 140. The pixel electrode 150, the intermediate layer 160, and the opposite electrode 170 may be disposed on the second organic insulating layer 105, and the thin-film encapsulation layer TFE may be disposed on the opposite electrode 170.

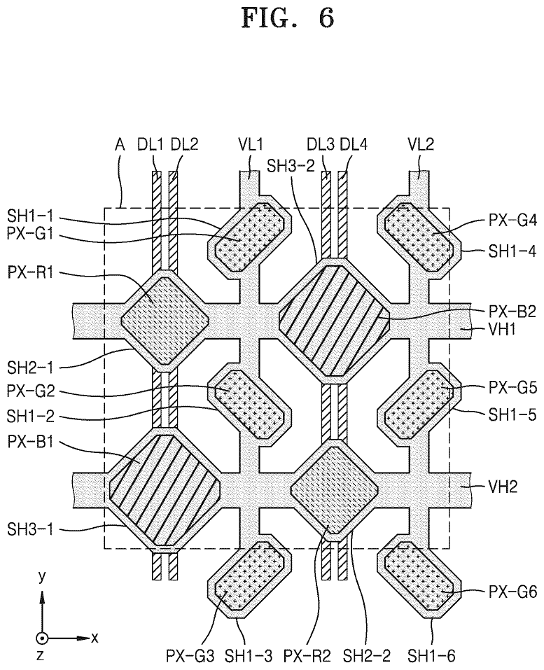

FIG. 6 is a schematic plan illustrating an enlarged example of the area A of FIG. 1.

Hereinafter, with reference to FIG. 6, redundant description of the same or substantially the same components as those described above with reference to FIGS. 1 to 5 may not be repeated.

Also, some of the components are shown in FIG. 6 for convenience of illustration, and other components may be more clearly understood with reference to some of the other drawings.

Referring to FIG. 6, the display apparatus according to an embodiment may include a first data line DL1, a second data line DL2, a third data line DL3, and a fourth data line DL4. Each of the first data line DL1, the second data line DL2, the third data line DL3, and the fourth data line DL4 may have the same or substantially the same characteristics as those of the first conductive layer 130 described above by being formed from a portion of the first conductive layer 130 described above.

The display apparatus according to an embodiment may include the substrate 100, a pixel circuit layer, the first conductive layer 130, the pixel electrode 150, the second conductive layer 140, and a first-1 light-emitting element PX-G1. The pixel circuit layer may be defined as a plurality of layers between the substrate 100 and the first conductive layer 130 from among the components shown in FIG. 4 or FIG. 5. For example, the pixel circuit layer according to an embodiment as illustrated in FIG. 4 may include the semiconductor layer 110, the first gate layer 120a, and the second gate layer 120b. For example, the pixel circuit layer according to an embodiment as illustrated in FIG. 5 may include the bottom metal layer BML, the semiconductor layer 110, the first gate layer 120a, the second gate layer 120b, the additional semiconductor layer 110′, and the third gate layer 120c.

The first conductive layer 130 may be disposed on the pixel circuit layer, and may include a plurality of data lines. The plurality of data lines may include the first data line DL1, the second data line DL2, the third data line DL3, and the fourth data line DL4, and in addition, may further include an n-th data line or the like (where n is a natural number greater than 1).

The pixel electrode 150 may include a plurality of pixel electrodes corresponding to a plurality of pixels, respectively, arranged in the display area DA. For example, the plurality of pixel electrodes may include a first pixel electrode, a second pixel electrode, and a third pixel electrode. The first pixel electrode corresponds to a first light-emitting element for emitting light in a first wavelength band, the second pixel electrode corresponds to a second light-emitting element for emitting light in a second wavelength band, and the third pixel electrode corresponds to a third light-emitting element for emitting light in a third wavelength band.

The second conductive layer 140 may be arranged between the first conductive layer 130 and the pixel electrode, and may include a plurality of power supply lines. In a plan view, the second conductive layer 140 may include a first-1 shielding portion SH1-1 overlapping with the first pixel electrode. In a plan view, the second conductive layer 140 may include a second-1 shielding portion SH2-1 overlapping with the second pixel electrode. In a plan view, the second conductive layer 140 may include a third-1 shielding portion SH3-1 overlapping with the third pixel electrode.

The second conductive layer 140 may further include a first-2 shielding portion SH1-2, a first-3 shielding portion SH1-3, a first-4 shielding portion SH1-4, a first-5 shielding portion SH1-5, a first-6 shielding portion SH1-6, or the like. The second conductive layer 140 may further include a second-2 shielding portion SH2-2, a third-2 shielding portion SH3-2, or the like.

For example, a pixel electrode disposed on the first-1 shielding portion SH1-1 may be referred to as a first-1 pixel electrode. A pixel electrode disposed on the first-2 shielding portion SH1-2 may be referred to as a first-2 pixel electrode. A pixel electrode disposed on the first-3 shielding portion SH1-3 may be referred to as a first-3 pixel electrode. A pixel electrode disposed on the first-4 shielding portion SH1-4 may be referred to as a first-4 pixel electrode. A pixel electrode disposed on the first-5 shielding portion SH1-5 may be referred to as a first-5 pixel electrode. A pixel electrode disposed on the first-6 shielding portion SH1-6 may be referred to as a first-6 pixel electrode.

For example, a pixel electrode disposed on the second-1 shielding portion SH2-1 may be referred to as a second-1 pixel electrode, and a pixel electrode disposed on the second-2 shielding portion SH2-2 may be referred to as a second-2 pixel electrode.

For example, the second-1 shielding portion SH2-1 may be arranged between the first conductive layer 130 and the second-1 pixel electrode, and may be disposed at (e.g., in or on) the same layer as that of the first-1 shielding portion SH1-1. Accordingly, a plurality of power lines, the first-1 shielding portion SH1-1, and the second-1 shielding portion SH2-1 may be integrated with each other.

For example, a pixel electrode disposed on the third-1 shielding portion SH3-1 may be referred to as a third-1 pixel electrode, and a pixel electrode disposed on the third-2 shielding portion SH3-2 may be referred to as a third-2 pixel electrode.

The third-1 shielding portion SH3-1 may be arranged between the first conductive layer 130 and the third-1 pixel electrode, and may be disposed at (e.g., in or on) the same layer as that of the first-1 shielding portion SH1-1. Accordingly, a plurality of power lines, the first-1 shielding portion SH1-1, the second-1 shielding portion SH2-1, and the third-1 shielding portion SH3-1 may be integrated with each other.

As such, a plurality of shielding portions and the plurality of power lines may all be disposed at (e.g., in or on) the same layer as each other, and may include the same material as each other, so that they may all be integrated with each other.

For example, each of the plurality of shielding portions may have a shield shape in a plan view.

For example, a shape of each of the plurality of shielding portions in a plan view may correspond to a shape of each of the plurality of light-emitting elements in a plan view (e.g., a shape of an emission area defined by a pixel defining layer in a plan view).

For example, an area of each of the plurality of shielding portions in a plan view may be greater than an area of each of the plurality of light-emitting elements in a plan view (e.g., an area of an emission area defined by a pixel defining layer in a plan view).

A first vertical power line VL1 may be integrated with the first-1 shielding portion SH1-1, the first-2 shielding portion SH1-2, the first-3 shielding portion SH1-3, or the like, and may be electrically connected to the first-1 shielding portion SH1-1, the first-2 shielding portion SH1-2, the first-3 shielding portion SH1-3, or the like. A second vertical power line VL2 may be integrated with the first-4 shielding portion SH1-4, the first-5 shielding portion SH1-5, the first-6 shielding portion SH1-6, or the like, and may be electrically connected to the first-4 shielding portion SH1-4, the first-5 shielding portion SH1-5, the first-6 shielding portion SH1-6, or the like.

A first horizontal power line VH1 may be integrated with the second-1 shielding portion SH2-1, the third-2 shielding portion SH3-2, or the like, and may be electrically connected to the second-1 shielding portion SH2-1, the third-2 shielding portion SH3-2, or the like. A second horizontal power line VH2 may be integrated with the third-1 shielding portion SH3-1, the second-2 shielding portion SH2-2, or the like, and may be electrically connected to the third-1 shielding portion SH3-1, the second-2 shielding portion SH2-2, or the like.

The plurality of power lines may include the driving voltage line PL illustrated in FIGS. 2 and 3, which transmits the first power supply voltage ELVDD. The plurality of power lines may be integrated with each other. The plurality of power lines may be integrally formed with each other, and may be concurrently or substantially simultaneously formed in the same process as each other. The plurality of power lines may be disposed at (e.g., in or on) the same layer as each other, and may include the same material as each other.

The plurality of power lines may include the first vertical power line VL1 and the second vertical power line VL2, which extend in the first direction y. The plurality of power lines may include the first horizontal power line VH1 and the second horizontal power line VH2, which extend in the second direction x crossing the first direction y. In addition, the plurality of power lines may further include an n-th vertical power line extending in the first direction, and may further include an n-th horizontal power line extending in the second direction (where n is a natural number greater than 1).

The first-1 shielding portion SH1-1 may be integrally formed with the plurality of power lines. In other words, the first-1 shielding portion SH1-1 may be disposed at (e.g., in or on) the same layer as that of the plurality of power lines, and may include the same material as that of the plurality of power lines. The first-1 shielding portion SH1-1 may be electrically connected to the plurality of power lines, and the first power supply voltage ELVDD may be applied thereto.

The first-1 shielding portion SH1-1 may serve to block a parasitic capacitor that may occur between the plurality of data lines and the first-1 pixel electrode. As such, the first-1 shielding portion SH1-1 may be disposed below the first-1 pixel electrode, and the first-1 shielding portion SH1-1 and the first-1 pixel electrode may overlap with each other in a plan view.

The plurality of shielding portions (e.g., the first-1 shielding portion SH1-1 to the third-2 shielding portion SH3-2, or the like) may serve to block parasitic capacitors that may occur between pixel electrodes (e.g., the first-1 pixel electrode to the third-2 pixel electrode, or the like) and a plurality of data lines. As such, the plurality of shielding portions may be arranged between the pixel electrodes and the plurality of data lines, and each of the plurality of shielding portions may be arranged to overlap with a corresponding pixel electrode in a plan view.

As shown in FIG. 6, the display apparatus according to an embodiment may include a first light-emitting element including the first-1 light-emitting element PX-G1 to a first-6 light-emitting element PX-G6 or the like, a second light-emitting element including a second-1 light-emitting element PX-R1 and a second-2 light-emitting element PX-R2 or the like, and a third light-emitting element including a third-1 light-emitting element PX-B1 and a third-2 light-emitting element PX-B2 or the like. For example, the first light-emitting element may be a pixel for emitting light in a first wavelength band, the second light-emitting element may be a pixel for emitting light in a second wavelength band, and the third light-emitting element may be a pixel for emitting light in a third wavelength band.

For example, the first-1 light-emitting element PX-G1 may be disposed on the first-1 pixel electrode, the first-2 light-emitting element PX-G2 may be disposed on the first-2 pixel electrode, the first-3 light-emitting element PX-G3 may be disposed on the first-3 pixel electrode, the first-4 light-emitting element PX-G4 may be disposed on the first-4 pixel electrode, the first-5 light-emitting element PX-G5 may be disposed on the first-5 pixel electrode, and the first-6 light-emitting element PX-G6 may be disposed on the first-6 pixel electrode.

For example, the second-1 light-emitting element PX-R1 may be disposed on the second-1 pixel electrode, the second-2 light-emitting element PX-R2 may be disposed on the second-2 pixel electrode, the third-1 light-emitting element PX-B1 may be disposed on the third-1 pixel electrode, and the third-2 light-emitting element PX-B2 may be disposed on the third-2 pixel electrode.

For example, in a plan view, a shape of the first-1 shielding portion SH1-1 may correspond to a shape of the first-1 light-emitting element PX-G1. In a plan view, an area of the first-1 light-emitting element PX-G1 may be less than an area of the first-1 shielding portion SH1-1.

For example, the first-1 shielding portion SH1-1 may be arranged between at least one of a plurality of data lines and the first-1 pixel electrode, the at least one of the plurality of data lines overlapping with the first-1 pixel electrode in a plan view.

For example, in a plan view, a shape of the second-1 shielding portion SH2-1 may correspond to a shape of the second-1 light-emitting element PX-R1. In a plan view, an area of the second-1 light-emitting element PX-R1 may be less than an area of the second-1 shielding portion SH2-1.

For example, the second-1 shielding portion SH2-1 may be arranged between at least one of the plurality of data lines and the second-1 pixel electrode, the at least one of the plurality of data lines overlapping with the second-1 pixel electrode in a plan view.

For example, in a plan view, a shape of the third-1 shielding portion SH3-1 may correspond to a shape of the third-1 light-emitting element PX-B1. In a plan view, an area of the third-1 light-emitting element PX-B1 may be less than an area of the third-1 shielding portion SH3-1.

For example, the third-1 shielding portion SH3-1 may be arranged between at least one of the plurality of data lines and the third-1 pixel electrode, the at least one of the plurality of data lines overlapping with the third-1 pixel electrode in a plan view.

For example, in a plan view, a shape of the first-2 shielding portion SH1-2 may correspond to a shape of the first-2 light-emitting element PX-G2. In a plan view, an area of the first-2 light-emitting element PX-G2 may be less than an area of the first-2 shielding portion SH1-2.

For example, in a plan view, a shape of the first-3 shielding portion SH1-3 may correspond to a shape of the first-3 light-emitting element PX-G3. In a plan view, an area of the first-3 light-emitting element PX-G3 may be less than an area of the first-3 shielding portion SH1-3.

For example, in a plan view, a shape of the first-4 shielding portion SH1-4 may correspond to a shape of the first-4 light-emitting element PX-G4. In a plan view, an area of the first-4 light-emitting element PX-G4 may be less than an area of the first-4 shielding portion SH1-4.

For example, in a plan view, a shape of the first-5 shielding portion SH1-5 may correspond to a shape of the first-5 light-emitting element PX-G5. In a plan view, an area of the first-5 light-emitting element PX-G5 may be less than an area of the first-5 shielding portion SH1-5.

For example, in a plan view, a shape of the first-6 shielding portion SH1-6 may correspond to a shape of the first-6 light-emitting element PX-G6. In a plan view, an area of the first-6 light-emitting element PX-G6 may be less than an area of the first-6 shielding portion SH1-6.

For example, in a plan view, a shape of the second-2 shielding portion SH2-2 may correspond to a shape of the second-2 light-emitting element PX-R2. In a plan view, an area of the second-2 light-emitting element PX-R2 may be less than an area of the second-2 shielding portion SH2-2.

For example, in a plan view, a shape of the third-2 shielding portion SH3-2 may correspond to a shape of the third-2 light-emitting element PX-B2. In a plan view, an area of the third-2 light-emitting element PX-B2 may be less than an area of the third-2 shielding portion SH3-2.

As shown in FIG. 6, the plurality of power lines included in the second conductive layer 140 may include the first vertical power line VL1, the second vertical power line VL2, or the like, which extend in the first direction y.

For example, in a plan view, the first vertical power line VL1 may overlap with the first-1 light-emitting element PX-G1. In a plan view, the first vertical power line VL1 may overlap with the first-2 light-emitting element PX-G2. In a plan view, the first vertical power line VL1 may overlap with the first-3 light-emitting element PX-G3.

For example, in a plan view, the second vertical power line VL2 may overlap with the first-4 light-emitting element PX-G4. In a plan view, the second vertical power line VL2 may overlap with the first-5 light-emitting element PX-G5. In a plan view, the second vertical power line VL2 may overlap with the first-6 light-emitting element PX-G6.

For example, in a plan view, the first horizontal power line VH1 may overlap with the second-1 light-emitting element PX-R1. In a plan view, the first horizontal power line VH1 may overlap with the third-2 light-emitting element PX-B2. In a plan view, the second horizontal power line VH2 may overlap with the third-1 light-emitting element PX-B1. In a plan view, the second horizontal power line VH2 may overlap with the second-2 light-emitting element PX-R2.

For example, in a plan view, the first data line DL1 may cross or intersect the first horizontal power line VH1 and the second horizontal power line VH2. In a plan view, the second data line DL2 may cross or intersect the first horizontal power line VH1 and the second horizontal power line VH2. In a plan view, the third data line DL3 may cross or intersect the first horizontal power line VH1 and the second horizontal power line VH2. In a plan view, the fourth data line DL4 may cross or intersect the first horizontal power line VH1 and the second horizontal power line VH2.

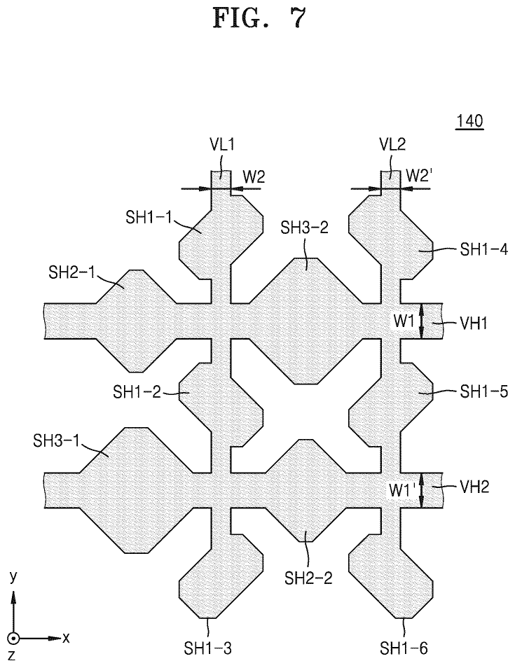

FIG. 7 is a schematic plan view of the second conductive layer of FIG. 6.

Hereinafter, with reference to FIG. 7, redundant description of the same or substantially the same components as those described above with reference to FIGS. 1 to 6 may not be repeated.

Referring to FIG. 7, a width W1 of the first horizontal power line VH1 may be equal to or approximately equal to a width W1′ of the second horizontal power line VH2. A width W2 of the first vertical power line VL1 may be equal to or approximately equal to a width W2′ of the second vertical power line VL2. For example, the width W1 of the first horizontal power line VH1 may be greater than the width W2 of the first vertical power line VL1. The width W1′ of the second horizontal power line VH2 may be greater than the width W2′ of the second vertical power line VL2.

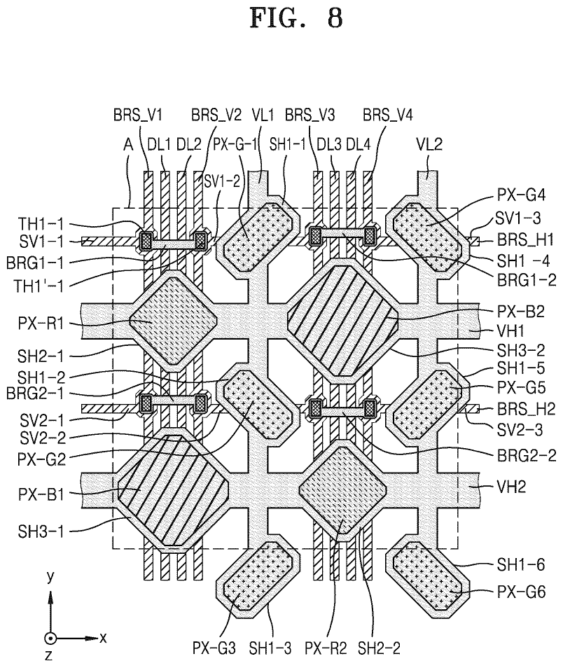

The conductive layer 140 of FIG. 7 may also be used in a display apparatus of FIG. 8 described in more detail below.

As shown in FIG. 7, the first horizontal power line VH1, the second horizontal power line VH2, the first vertical power line VL1, and the second vertical power line VL2 may be integrated with each other.

The first horizontal power line VH1, the second horizontal power line VH2, the first vertical power line VL1, and the second vertical power line VL2 may be concurrently or substantially simultaneously formed with each other in the same process.

The first horizontal power line VH1, the second horizontal power line VH2, the first vertical power line VL1, and the second vertical power line VL2 may be positioned at (e.g., in or on) the same layer as each other, and may include the same material as each other.

In other words, a plurality of vertical power lines and a plurality of horizontal power lines may be integrated with each other. The plurality of vertical power lines and the plurality of horizontal power lines may be positioned at (e.g., in or on) the same layer as each other, and may include the same material as each other.

As shown in FIG. 7, the first-1 shielding portion SH1-1 to the third-2 shielding portion SH3-2 may be integrated with the plurality of vertical power lines and the plurality of horizontal power lines. The first-1 shielding portion SH1-1 to the third-2 shielding portion SH3-2 may be positioned at (e.g., in or on) the same layer as that of the plurality of vertical power lines and the plurality of horizontal power lines, and may include the same material as that of the plurality of vertical power lines and the plurality of horizontal power lines.

In other words, a plurality of shielding portions, the plurality of vertical power lines, and the plurality of horizontal power lines may be integrated with each other. The plurality of shielding portions, the plurality of vertical power lines, and the plurality of horizontal power lines may be positioned at (e.g., in or on) the same layer as each other, and may include the same material as each other.

FIG. 8 is a schematic plan view mainly illustrating another example of the area A of FIG. 1.

Hereinafter, with reference to FIG. 8, redundant description of the same or substantially the same components as those described above with reference to FIGS. 1 to 7 may not be repeated.

Referring to FIG. 8, the first conductive layer 130 may further include a first vertical data line BRS_V1 and a second vertical data line BRS_V2. In addition, the first conductive layer 130 may further include a first horizontal data line BRS_H1 and a second horizontal data line BRS_H2.

The first vertical data line BRS_V1 may be arranged around (e.g., adjacent to) a plurality of data lines, and may extend in the first direction y. The second vertical data line BRS_V2 may be arranged around (e.g., adjacent to) the plurality of data lines, and may extend in the first direction y. The second vertical data line BRS_V2 may be spaced apart from the first vertical data line BRS_V1 in a plan view. For example, the first data line DL1 and the second data line DL2 may be arranged between the first vertical data line BRS_V1 and the second vertical data line BRS_V2 in a plan view. For example, the first data line DL1 and the second data line DL2 may be disposed at (e.g., in or on) the same layer as that of the first vertical data line BRS_V1 and the second vertical data line BRS_V2, and may include the same material as that of the first vertical data line BRS_V1 and the second vertical data line BRS_V2.

A third vertical data line BRS_V3 may be arranged around (e.g., adjacent to) a plurality of data lines, and may extend in the first direction. A fourth vertical data line BRS_V4 may be arranged around the plurality of data lines, and may extend in the first direction. The fourth vertical data line BRS_V4 may be spaced apart from the third vertical data line BRS_V3 in a plan view. For example, the third data line DL3 and the fourth data line DL4 may be arranged between the third vertical data line BRS_V3 and the fourth vertical data line BRS_V4 in a plan view. For example, the third data line DL3 and the fourth data line DL4 may be disposed at (e.g., in or on) the same layer as that of the third vertical data line BRS_V3 and the fourth vertical data line BRS_V4, and may include the same material as that of the third vertical data line BRS_V3 and the fourth vertical data line BRS_V4.

The first horizontal data line BRS_H1 may extend in the second direction x crossing the first direction y, and may be electrically connected to the first vertical data line BRS_V1 and to the second vertical data line BRS_V2. The first horizontal data line BRS_H1 may be electrically connected to the third vertical data line BRS_V3 and to the fourth vertical data line BRS_V4.

The second horizontal data line BRS_H2 may extend in the second direction crossing the first direction, and may be electrically connected to the first vertical data line BRS_V1 and to the second vertical data line BRS_V2. The second horizontal data line BRS_H2 may be electrically connected to the third vertical data line BRS_V3 and to the fourth vertical data line BRS_V4.

For example, in a plan view, the first horizontal data line BRS_H1 and the second horizontal data line BRS_H2 may be spaced apart from each other. In a plan view, the first horizontal power line VH1 may be arranged between the first horizontal data line BRS_H1 and the second horizontal data line BRS_H2. For example, in a plan view, the second-1 shielding portion SH2-1 and the third-2 shielding portion SH3-2 may be arranged between the first horizontal data line BRS_H1 and the second horizontal data line BRS_H2.

In addition, for convenience of illustration, the first vertical data line BRS_V1 to the fourth vertical data line BRS_V4, the first horizontal data line BRS_H1, and the second horizontal data line BRS_H2 are shown, but the present disclosure is not limited thereto, and more vertical data lines and more horizontal data lines may be included.

As shown in FIG. 8, the first horizontal data line BRS_H1 may include a first-1 horizontal data line SV1-1, a first-2 horizontal data line SV1-2, and a first-3 horizontal data line SV1-3. The first-1 horizontal data line SV1-1, the first-2 horizontal data line SV1-2, and the first-3 horizontal data line SV1-3 may be disposed at (e.g., in or on) the same layer as each other, but may be electrically separated from each other. To electrically connect the first-1 horizontal data line SV1-1, the first-2 horizontal data line SV1-2, and the first-3 horizontal data line SV1-3 to each other, the second conductive layer 140 may further include a first-1 bridge line BRG1-1 and a first-2 bridge line BRG1-2.

For example, the first horizontal data line BRS_H1 may include the first-1 horizontal data line SV1-1, the first-2 horizontal data line SV1-2, and the first-3 horizontal data line SV1-3, which are electrically separated from each other, and the first-1 horizontal data line SV1-1 and the first-2 horizontal data line SV1-2 may be electrically connected to each other by the first-1 bridge line BRG1-1 formed at (e.g., in or on) the same layer as that of the second conductive layer 140. The first-1 bridge line BRG1-1 may include the same material as that of the second conductive layer 140. In a plan view, the first-1 bridge line BRG1-1 may be spaced apart from a plurality of power lines and a plurality of shielding portions.

For example, the first horizontal data line BRS_H1 may include the first-1 horizontal data line SV1-1, the first-2 horizontal data line SV1-2, and the first-3 horizontal data line SV1-3, which are electrically separated from each other, and the first-2 horizontal data line SV1-2 and the first-3 horizontal data line SV1-3 may be electrically connected to each other by the first-2 bridge line BRG1-2 formed at (e.g., in or on) the same layer as that of the second conductive layer 140. The first-2 bridge line BRG1-2 may include the same material as that of the second conductive layer 140. In a plan view, the first-2 bridge line BRG1-2 may be spaced apart from the plurality of power lines and the plurality of shielding portions.

As shown in FIG. 8, the second horizontal data line BRS_H2 may include a second-1 horizontal data line SV2-1, a second-2 horizontal data line SV2-2, and a second-3 horizontal data line SV2-3. The second-1 horizontal data line SV2-1, the second-2 horizontal data line SV2-2, and the second-3 horizontal data line SV2-3 may be disposed at (e.g., in or on) the same layer as each other, but may be electrically separated from each other. To electrically connect the second-1 horizontal data line SV2-1, the second-2 horizontal data line SV2-2, and the second-3 horizontal data line SV2-3 to each other, the second conductive layer 140 may further include a second-1 bridge line BRG2-1 and a second-2 bridge line BRG2-2.

For example, the second horizontal data line BRS_H2 may include the second-1 horizontal data line SV2-1, the second-2 horizontal data line SV2-2, and the second-3 horizontal data line SV2-3, which are electrically separated from each other, and the second-1 horizontal data line SV2-1 and the second-2 horizontal data line SV2-2 may be electrically connected to each other by the second-1 bridge line BRG2-1 formed at (e.g., in or on) the same layer as that of the second conductive layer 140. The second-1 bridge line BRG2-1 may include the same material as that of the second conductive layer 140. In a plan view, the second-1 bridge line BRG2-1 may be spaced apart from a plurality of power lines and a plurality of shielding portions.

For example, the second horizontal data line BRS_H2 may include the second-1 horizontal data line SV2-1, the second-2 horizontal data line SV2-2, and the second-3 horizontal data line SV2-3, which are electrically separated from each other, and the second-2 horizontal data line SV2-2 and the second-3 horizontal data line SV2-3 may be electrically connected to each other by the second-2 bridge line BRG2-2 formed at (e.g., in or on) the same layer as that of the second conductive layer 140. The second-2 bridge line BRG2-2 may include the same material as that of the second conductive layer 140. In a plan view, the second-2 bridge line BRG2-2 may be spaced apart from a plurality of power lines and a plurality of shielding portions.

For example, the first horizontal power line VH1 may be arranged to cross or intersect the first vertical data line BRS_V1 and the second vertical data line BRS_V2 in a plan view. The first horizontal power line VH1 may be arranged to cross or intersect the third vertical data line BRS_V3 and the fourth vertical data line BRS_V4 in a plan view.

For example, the second horizontal power line VH2 may be arranged to cross or intersect the first vertical data line BRS_V1 and the second vertical data line BRS_V2 in a plan view. The second horizontal power line VH2 may be arranged to cross or intersect the third vertical data line BRS_V3 and the fourth vertical data line BRS_V4 in a plan view.

For example, a width (e.g., refer to W1 of FIG. 7) of the first horizontal power line VH1 may be greater than a width (e.g., refer to W2 of FIG. 7) of the first vertical power line VL1. The width (e.g., refer to W1 of FIG. 7) of the first horizontal power line VH1 may be greater than a width (e.g., refer to W1′ of FIG. 7) of the second vertical power line VL2.

The first horizontal power line VH1 may pass through lower portions of the second-1 light-emitting element PX-R1 and the third-2 light-emitting element PX-B2. The second horizontal power line VH2 may pass through lower portions of the third-1 light-emitting element PX-B1 and the second-2 light-emitting element PX-R2.

The first vertical power line VL1 may pass through lower portions of the first-1 light-emitting element PX-G1 and the first-2 light-emitting element PX-G2. The second vertical power line VL2 may pass through lower portions of the first-4 light-emitting element PX-G4 and the first-5 light-emitting element PX-G5.

An area of each of the second-1 light-emitting element PX-R1, the third-2 light-emitting element PX-B2, the third-1 light-emitting element PX-B1, and the second-2 light-emitting element PX-R2 in a plan view may be greater than an area of each of the first-1 light-emitting element PX-G1, the first-2 light-emitting element PX-G2, the first-4 light-emitting element PX-G4, and the first-5 light-emitting element PX-G5.

Accordingly, the width W1 of the first horizontal power line VH1 and the width W1′ of the second horizontal power line VH2, which pass through lower portions of light-emitting elements having a relatively larger area, may be greater than the width W2 of the first vertical power line VL1 and the width W2′ of the second vertical power line VL2. As a result, a density of a charge amount passing through shielding portions may be maintained or substantially maintained to be constant.

In other words, a ratio of the width W1 of the first horizontal power line VH1 and the width W2 of the first vertical power line VL1 may be between an area of the light-emitting pixels that the first horizontal power line VH1 passes through lower portions thereof in a plan view and an area of the light-emitting pixels that the first vertical power line VL1 passes through lower portions thereof in a plan view.

In other words, a ratio of the width W1 of the first horizontal power line VH1 and the width W2′ of the second vertical power line VL2 may be between an area of the light-emitting pixels that the first horizontal power line VH1 passes through lower portions thereof in a plan view and an area of the light-emitting pixels that the second vertical power line VL2 passes through lower portions thereof in a plan view.

In other words, a ratio of the width W1′ of the second horizontal power line VH2 and the width W2 of the first vertical power line VL1 may be between an area of the light-emitting pixels that the second horizontal power line VH2 passes through lower portions thereof in a plan view and an area of the light-emitting pixels that the first vertical power line VL1 passes through lower portions thereof in a plan view.

In other words, a ratio of the width W1′ of the second horizontal power line VH2 and the width W2′ of the second vertical power line VL2 may be between an area of the light-emitting pixels that the second horizontal power line VH2 passes through lower portions thereof in a plan view and an area of the light-emitting pixels that the second vertical power line VL2 passes through lower portions thereof in a plan view.

For example, the width (e.g., refer to W1′ of FIG. 7) of the second horizontal power line VH2 may be greater than the width (e.g., refer to W2 of FIG. 7) of the first vertical power line VL1. The width (e.g., refer to W1′ of FIG. 7) of the second horizontal power line VH2 may be greater than the width (e.g., refer to W2′ of FIG. 7) of the second vertical power line VL2.

As shown in FIGS. 6 to 8, the display apparatus according to one or more embodiments includes a plurality of shielding portions integrally formed with a plurality of power lines configuring a second conductive layer, and thus, parasitic capacitors that may formed between data lines and pixel electrodes may be reduced or prevented.

As the plurality of shielding portions are integrally formed with the plurality power lines, the first power supply voltage ELVDD may be applied to each of the plurality of shielding portions. Accordingly, the plurality of shielding portions to which the first power supply voltage ELVDD is applied may more effectively prevent or reduce the parasitic capacitors that may be formed between the data lines and the pixel electrodes.

As the parasitic capacitors are prevented or reduced, a mura phenomenon that may occur in the display apparatus or the display panel 10 may also be prevented or reduced.

TABLE 1
(in which a unit is F):

| | | | | parasitic capacitor (2) between | | |
|---|---|---|---|---|---|---|
| | parasitic capacitor (1) between | | | vertical data line, horizontal | | |
| | data line and pixel electrode | | | data line, and pixel electrode | | |
| | R | G | B | R | G | B |
| Comparative | 2.27E−15 | 3.39E−18 | 2.64E−15 | 2.03E−15 | 1.24E−16 | 2.59E−15 |
| Example | | | | | | |
| FIG. 8 | 3.39E−16 | 1.07E−16 | 4.24E−16 | 1.02E−15 | 9.04E−16 | 1.29E−15 |

TABLE 2
(in which a unit is F):

parasitic capacitor (1) + parasitic capacitor (2)

| | R | G | B |
|---|---|---|---|
| Comparative | 4.30E−15 | 1.27E−16 | 5.23E−15 |
| Example | | | |
| FIG. 8 | 1.36E−15 | 1.01E−15 | 1.71E−15 |

Unlike that of a display apparatus according to an embodiment, a display apparatus according to a comparative example does not separately include a plurality of shielding portions, but includes the same components other than the plurality of shielding portions as those of the display apparatus according to the embodiment. The display apparatus of the comparative example and the display apparatus according to the embodiment are display apparatuses having the same specifications as each other with no differences in terms of the components other than the presence or absence of the plurality of shielding portions.

Referring to Table 1 and Table 2 above, a difference between the parasitic capacitor measured in the display apparatus illustrated in FIG. 8 and the parasitic capacitor measured in the display apparatus according to the comparative example is shown. As shown in Table 1 and Table 2, the display apparatus illustrated in FIG. 8 including the plurality of shielding portions may have a parasitic capacitor of a much smaller size than that of the display apparatus according to the comparative example.

In addition, when only the parasitic capacitor (1) is compared, it is clear that the display apparatus illustrated in FIG. 6 may have a parasitic capacitor of a much smaller size than that of the display apparatus according to the comparative example.

Also, in a plan view, an area of each of the plurality of shielding portions may be greater than an area of a corresponding pixel electrode. As such a viewing angle of the display apparatus may be improved. In other words, a viewing angle of the display apparatuses illustrated in FIGS. 6 to 8 may be improved when compared to a viewing angle of the display apparatus according to the comparative example.

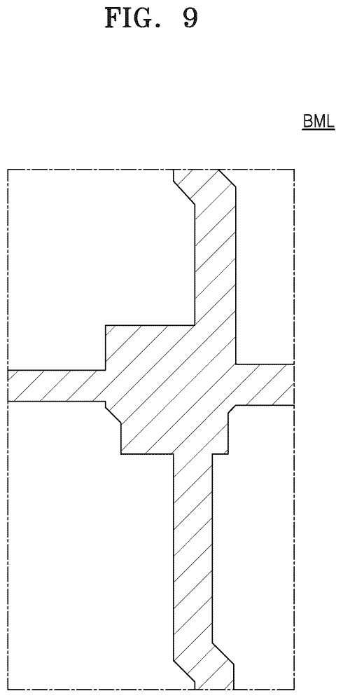

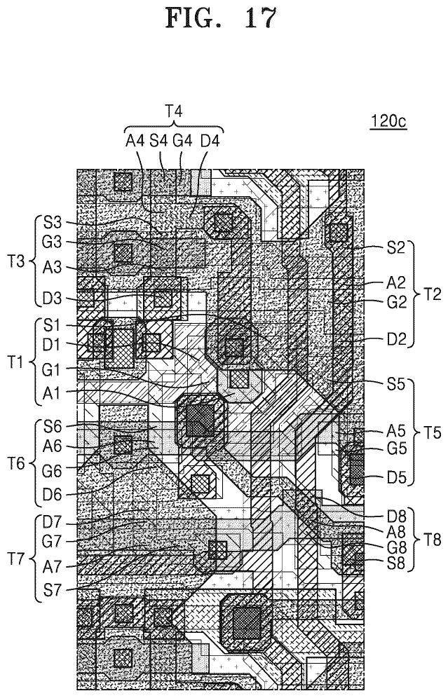

FIGS. 9 through 16 are example layout diagrams schematically illustrating various layers of components of a partial area of the area A of FIG. 1. FIG. 17 is a layout diagram schematically illustrating an example of an overlap of the layout diagrams of FIGS. 9 through 16.

Hereinafter, with reference to FIGS. 9 to 17, redundant description of the same or substantially the same components as those described above with reference to FIGS. 1 to 8 may not be repeated.

Referring to FIG. 9, a portion of the bottom metal layer BML may have a shape corresponding to a shape of a first electrode of a storage capacitor described in more detail below. The bottom metal layer BML may prevent or substantially prevent external light from reaching the lines. Also, the bottom metal layer BML may prevent or substantially prevent external light from reaching the semiconductor layer 110. The bottom metal layer BML may include a metal, such as silver, copper, aluminum, or the like.

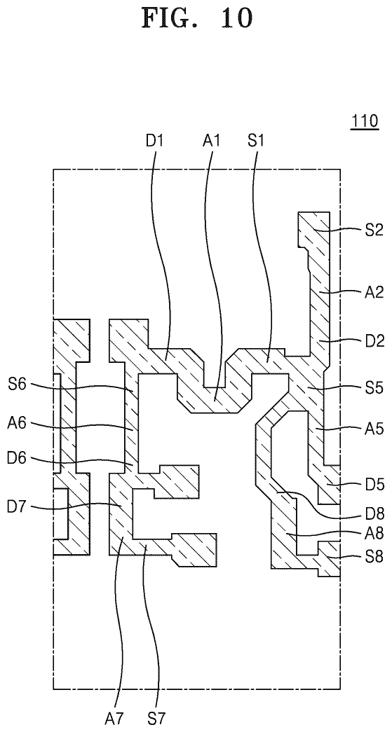

Referring FIG. 10, the semiconductor layer 110 may include a first drain area D1, a first channel area A1, and a first source area S1 of a first transistor. The semiconductor layer 110 may include a second drain area D2, a second channel area A2, and a second source area S2 of a second transistor. The semiconductor layer 110 may include a fifth drain area D5, a fifth channel area A5, and a fifth source area S5 of a fifth transistor. The semiconductor layer 110 may include a sixth drain area D6, a sixth channel area A6, and a sixth source area S6 of a sixth transistor. The semiconductor layer 110 may include a seventh drain area D7, a seventh channel area A7, and a seventh source area S7 of a seventh transistor. The semiconductor layer 110 may include an eighth drain area D8, an eighth channel area A8, and an eighth source area S8 of an eighth transistor.

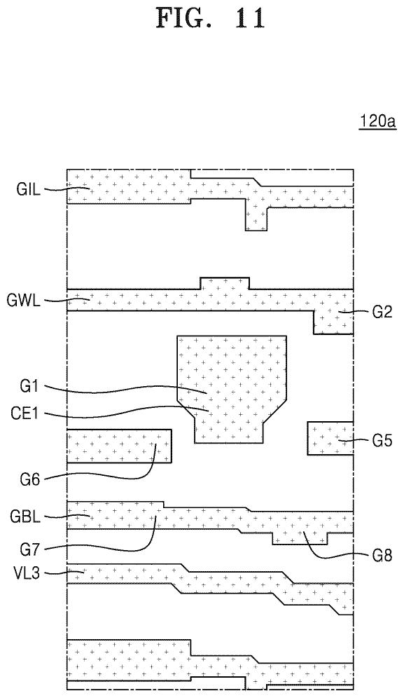

Referring to FIG. 11, the first gate layer 120a may include the first gate line GWL to transmit the first gate signal GW, the second gate line GIL to transmit the second gate signal GI, and the fourth gate line GBL to transmit the fourth gate signal GB. The first gate layer 120a may further include the bias voltage line VL3 to transmit the on-bias voltage VOBS.

The first gate layer 120a may include a first gate area G1 of the first transistor, a second gate area G2 of the second transistor, a fifth gate area G5 of the fifth transistor, a sixth gate area G6 of the sixth transistor, a seventh gate area G7 of the seventh transistor, and an eighth gate area G8 of the eighth transistor. The first gate layer 120a may further include the first electrode CE1 of the storage capacitor Cst.

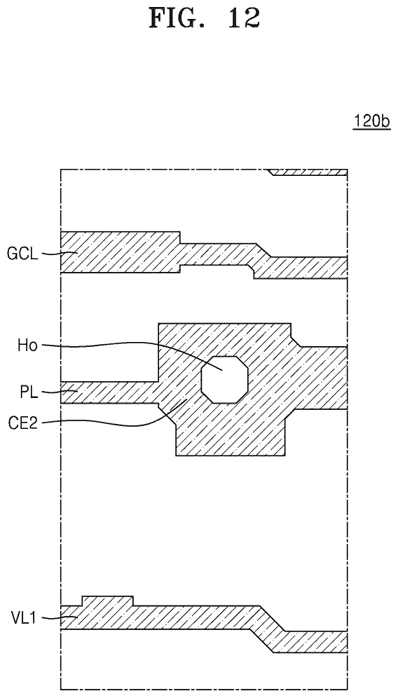

Referring to FIG. 12, the second gate layer 120b may include the third gate line GCL to transmit the third gate signal GC, and the first initialization voltage line VL1 to transmit the first initialization voltage VINT. The second gate layer 120b may further include the driving voltage line PL to transmit the first power supply voltage ELVDD. The second gate layer 120b may further include the second electrode CE2 included in the storage capacitor Cst. The second electrode CE2 may have a through hole.

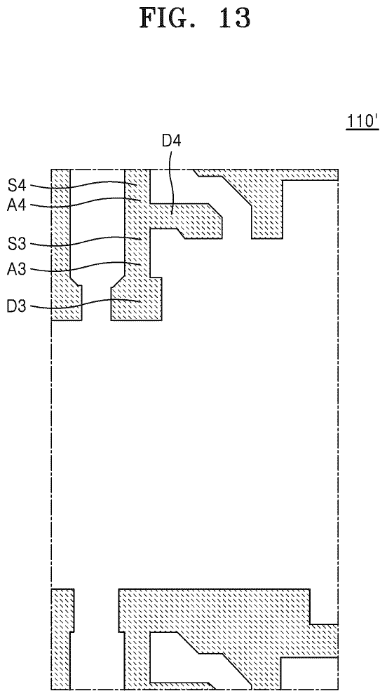

Referring to FIG. 13, the additional semiconductor layer 110′ may include a third drain area D3, a third channel area A3, and a third source area S3 of a third transistor. The additional semiconductor layer 110′ may include a fourth drain area D4, a fourth channel area A4, and a fourth source area S4 of a fourth transistor.

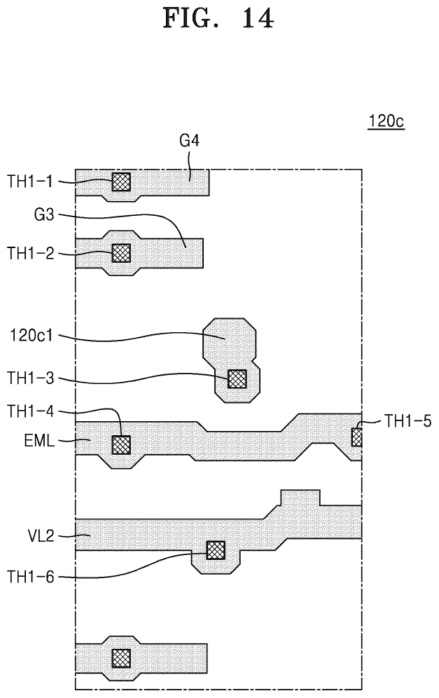

Referring to FIG. 14, the third gate layer 120c may include a third gate area G3 of the third transistor, and a fourth gate area G4 of the fourth transistor. The third gate layer 120c may further include the second initialization voltage line VL2 to transmit the second initialization voltage VAINT, and the emission control line EML to transmit the emission control signal EM.

The third gate layer 120c may further include a first-1 through hole TH1-1 arranged around the fourth gate area G4, a first-2 through hole TH1-2 arranged around the third gate area G3, a first-4 through hole TH1-4 and a first-5 through hole TH1-5 formed in the emission control line EML, and a first-6 through hole TH1-6 formed in the second initialization voltage line VL2.

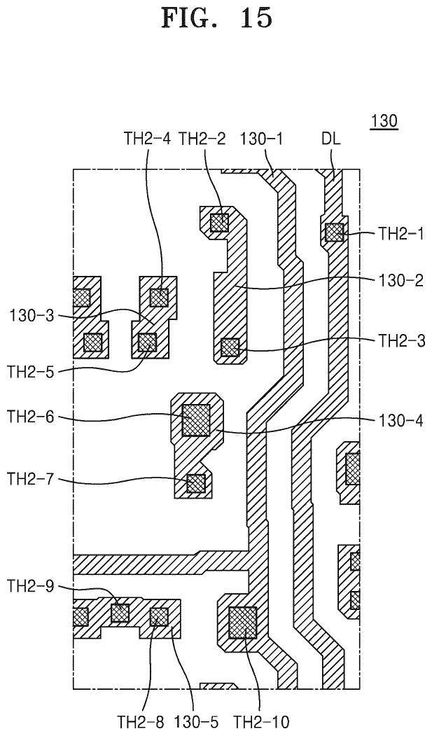

1 Referring to FIG. 15, the first conductive layer 130 may include a first-1 conductive portion 130-1, a first-2 conductive portion 130-2, a first-3 conductive portion 130-3, a first-4 conductive portion 130-4, and a first-5 conductive portion 130-5. The first conductive layer 130 may further include the data line DL to transmit a data signal.

The first conductive layer 130 may further include a second-1 through hole TH2-1 formed in the data line DL, a second-2 through hole TH2-2 and a second-3 through hole TH2-3 formed in the first-2 conductive portion 130-2, a second-4 through hole TH2-4 and a second-5 through hole TH2-5 formed in the first-3 conductive portion 130-3, a second-6 through hole TH2-6 and a second-7 through hole TH2-7 formed in the first-4 conductive portion 130-4, a second-8 through hole TH2-8 and a second-9 through hole TH2-9 formed in the first-5 conductive portion 130-5, and a second-10 through hole TH2-10 formed in the first-1 conductive portion 130-1.

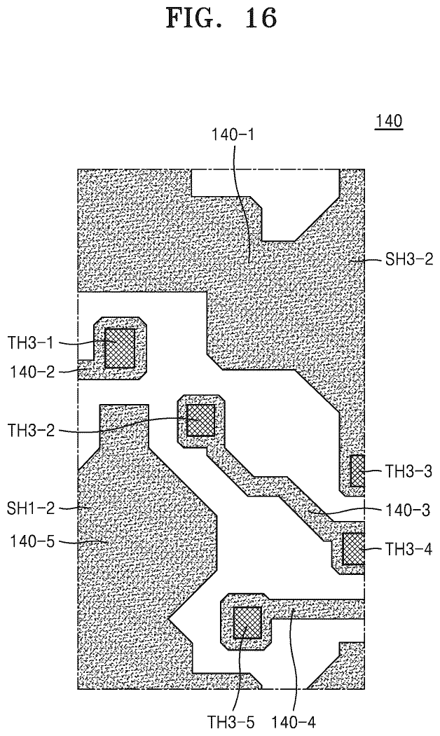

Referring to FIG. 16, the second conductive layer 140 may include a second-1 conductive portion 140-1, a second-2 conductive portion 140-2, a second-3 conductive portion 140-3, and a second-5 conductive portion 140-5. For example, a portion of the second-1 conductive portion 140-1 may be the third-2 shielding portion SH3-2. For example, a portion of the second-5 conductive portion 140-5 may be the first-2 shielding portion SH1-2.

The second conductive layer 140 may further include a third-1 through hole TH3-1 formed in the second-2 conductive portion 140-2, a third-2 through hole TH3-2 and a third-4 through hole TH3-4 formed in the second-3 conductive portion 140-3, a third-3 through hole TH3-3 formed in the second-1 conductive portion 140-1, and a third-5 through hole TH3-5 formed in the second-4 conductive portion 140-4.

As such, the bottom metal layer BML, the semiconductor layer 110, the first gate layer 120a, the second gate layer 120b, the additional semiconductor layer 110′, the third gate layer 120c, the first conductive layer 130, and the second conductive layer 140 may be stacked on one another as shown in FIG. 17.

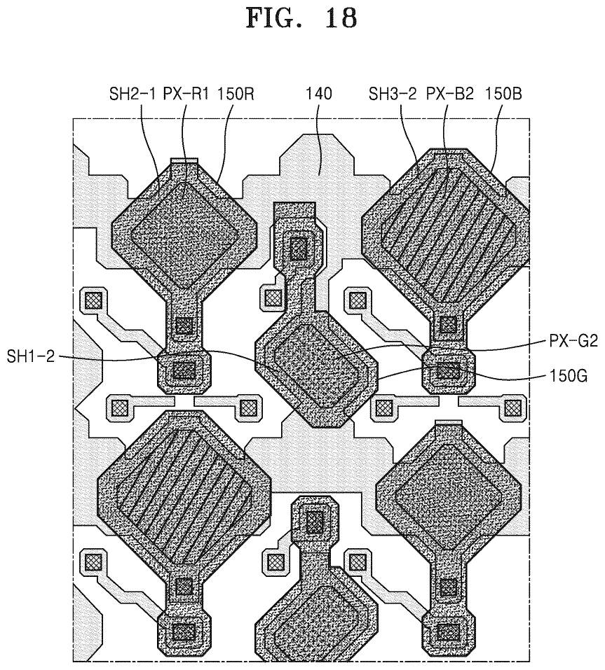

FIG. 18 is an example enlarged layout diagram schematically illustrating a stacked layout of a second conductive layer, a light-emitting element, and a pixel electrode according to an embodiment.

Hereinafter, with reference to FIG. 18, redundant description of the same or substantially the same components as those described above with reference to FIGS. 1 to 17 may not be repeated.

Referring to FIG. 18, in a plan view, an area of one pixel electrode may be greater than an area of one shielding portion corresponding to the one pixel electrode.

For example, in a plan view, an area of the second-1 shielding portion SH2-1 may be less than an area of a second-1 pixel electrode 150R corresponding to the second-1 shielding portion SH2-1.

For example, in a plan view, an area of the third-2 shielding portion SH3-2 may be less than an area of a third-2 pixel electrode 150B corresponding to the third-2 shielding portion SH3-2.

For example, in a plan view, an area of the first-2 shielding portion SH1-2 may be less than an area of a first-2 pixel electrode 150G corresponding to the first-2 shielding portion SH1-2.

According to one or more embodiments of the present disclosure as described above, a display apparatus capable of reducing an effect of a parasitic capacitor may be implemented. However, the aspects and features of the present disclosure are not limited thereto.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display apparatus comprising:
a substrate;
a pixel circuit layer on the substrate;
a first conductive layer on the pixel circuit layer, and comprising a plurality of data lines;
a first-1 pixel electrode on the first conductive layer;
a second conductive layer between the first conductive layer and the first-1 pixel electrode, and comprising:
a plurality of power lines; and
a first-1 shielding portion overlapping with the first-1 pixel electrode in a plan view; and
a first-1 light-emitting element on the first-1 pixel electrode,
wherein the plurality of power lines and the first-1 shielding portion are integrated with each other.

2. The display apparatus of claim 1, further comprising:
a second-1 pixel electrode on the first conductive layer and at a same layer as that of the first-1 pixel electrode;
a second-1 light-emitting element on the second-1 pixel electrode;
a third-1 pixel electrode on the first conductive layer and at a same layer as that of the second-1 pixel electrode; and
a third-1 light-emitting element on the third-1 pixel electrode.

3. The display apparatus of claim 2, wherein the second conductive layer further comprises a second-1 shielding portion at a same layer as that of the first-1 shielding portion, and located between the first conductive layer and the second-1 pixel electrode.

4. The display apparatus of claim 3, wherein the plurality of power lines, the first-1 shielding portion, and the second-1 shielding portion are integrated with each other.

5. The display apparatus of claim 4, wherein the plurality of power lines comprises:
a first vertical power line extending in a first direction; and
a first horizontal power line extending in a second direction crossing the first direction, and integrated with the first vertical power line.

6. The display apparatus of claim 4, wherein the second conductive layer further comprises a third-1 shielding portion at a same layer as that of the first-1 shielding portion, and located between the first conductive layer and the second-1 pixel electrode.

7. The display apparatus of claim 1, wherein, in a plan view, a shape of the first-1 shielding portion corresponds to a shape of the first-1 light-emitting element.

8. The display apparatus of claim 1, wherein, in a plan view, an area of the first-1 light-emitting element is less than an area of the first-1 shielding portion.

9. The display apparatus of claim 8, wherein the first-1 shielding portion is located between at least one of the plurality of data lines and the first-1 pixel electrode, the at least one of the plurality of data lines overlapping with the first-1 pixel electrode in a plan view.

10. The display apparatus of claim 3, wherein, in a plan view, a shape of the second-1 shielding portion corresponds to a shape of the second-1 light-emitting element.

11. The display apparatus of claim 3, wherein, in a plan view, an area of the second-1 light-emitting element is less than an area of the second-1 shielding portion.

12. The display apparatus of claim 11, wherein the second-1 shielding portion is located between at least one of the plurality of data lines and the second-1 pixel electrode, the at least one of the plurality of data lines overlapping with the second-1 pixel electrode in a plan view.

13. The display apparatus of claim 6, wherein, in a plan view, a shape of the third-1 shielding portion corresponds to a shape of the third-1 light-emitting element.

14. The display apparatus of claim 6, wherein, in a plan view, an area of the third-1 light-emitting element is less than an area of the third-1 shielding portion.

15. The display apparatus of claim 14, wherein the third-1 shielding portion is located between at least one of the plurality of data lines and the third-1 pixel electrode, the at least one of the plurality of data lines overlapping with the third-1 pixel electrode in a plan view.

16. The display apparatus of claim 1, wherein the first conductive layer further comprises:
a first vertical data line around the plurality of data lines, and extending in a first direction; and
a first horizontal data line extending in a second direction crossing the first direction, and electrically connected to the first vertical data line.

17. The display apparatus of claim 16, wherein the first horizontal data line comprises a first-1 horizontal data line, and a first-2 horizontal data line spaced from the first-1 horizontal data line, and
wherein the first-1 horizontal data line and the first-2 horizontal data line are electrically connected to each other by a first-1 bridge line at a same layer as that of the second conductive layer.

18. The display apparatus of claim 17, wherein the first-1 bridge line comprises a same material as that of the second conductive layer.

19. The display apparatus of claim 18, wherein, in a plan view, the first-1 bridge line is spaced from the plurality of power lines and the first-1 shielding portion.

20. The display apparatus of claim 1, wherein, in a plan view, an area of the first-1 pixel electrode is greater than an area of the first-1 shielding portion.
